(19) United States
(12) Patent Application Publication
(10) Pub. No.: US 2024/0370613 A1
(43) Pub. Date: Nov. 7, 2024

(54) PROCESS-BASED DIAGENETIC MODELING FOR CLASTIC RESERVOIR QUALITY PREDICTION

(71) Applicant: SAUDI ARABIAN OIL COMPANY, Dhahran (SA)

(72) Inventors: Wei Wei, Beijing (CN); Peng Lu, Dhahran (SA); Xiaoxi Wang, Beijing (CN)

(73) Assignees: SAUDI ARABIAN OIL COMPANY, Dhahran (SA); ARAMCO FAR EAST (BEIJING) BUSINESS SERVICES CO., LTD., Beijing (CN)

(21) Appl. No.: 18/247,388

(22) PCT Filed: Mar. 28, 2022
(86) PCT No.: PCT/CN2022/083254

§ 371 Date: Mar. 30, 2023

(51) Int. Cl. G06F 30/28

(52) U.S. Cl. CPC G06F 30/28

(57) ABSTRACT

A method for predicting a quality of a reservoir, including the steps: drilling a well that penetrates the reservoir, acquiring one-dimensional (1D) input data (1204) from the well, wherein the input data (1204) include: depositional temperature and burial depth as function of a depositional time, and facies data and compaction data (1208), adding a time interval to the depositional time, entering the 1D input data (1204) in a diagenesis model, wherein the diagenesis model includes a compaction model that outputs a predicted compaction at a depositional time, and a cementation model that outputs a predicted cementation at the depositional time, repeating the previous two steps until the depositional time is the present time, and the diagenesis model outputs a predicted compaction curve with porosity as function of depth.

### BACKGROUND

Reservoir characterization is used to simulate the behavior of hydrocarbons in the reservoir under different circumstances and to find the optimal production techniques that will maximize the production. Reservoir characterization incorporates the characteristics of the reservoir pertinent to the ability of the reservoir to store and produce hydrocarbons. Reservoir quality predicts commercial quantities of hydrocarbons in a reservoir and is a geologic, engineering, and economic assessment of the reservoir.

Reservoir quality is one of the important uncertainties in reservoir characterization. However, the current approaches for predicting reservoir quality are commonly limited in applicability or require input data that are poorly constrained or difficult to obtain or are of unproven accuracy. The accuracy of these traditional approaches is constrained to well log (measurement of physical quantities in an oil well versus depth) and petrographic data (data from examination of rocks in thin section). Thus, it is difficult to apply these approaches to the frontier areas with limited wells.

Accordingly, there exists a need fora method for predicting the reservoir quality.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method for predicting a quality of a reservoir, comprising the steps: drilling a well that penetrates the reservoir, acquiring one-dimensional (1D) input data from the well, wherein the input data comprise: depositional temperature and burial depth as function of a depositional time, and facies data and compaction data, adding a time interval to the depositional time, entering the 1D input data in a diagenesis model, wherein the diagenesis model comprises a compaction model that outputs a predicted compaction at a depositional time, and a cementation model that outputs a predicted cementation at the depositional time, repeating the previous two steps until the depositional time is the present time, and the diagenesis model outputs a predicted compaction curve with porosity as function of depth.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 shows a flowchart of the method steps for predicting a quality of a reservoir with 1D input data, according to one or more embodiments.

FIG. 2 shows compaction curves of five types of sedimentary facies, according to one or more embodiments.

FIG. 3 shows predicted curves for compacted porosity, quartz cement, illite cement, final porosity with burial depth of the target well, according to one or more embodiments.

FIG. 4 shows permeability variation with burial depth of a sample well with dunes as the facies, according to one or more embodiments.

FIG. 5 shows a flowchart 500 of the method steps for predicting a quality of a reservoir with 2D input data, according to one or more embodiments.

FIG. 6 shows the sedimentary facies map at the present time used for 2D modeling, according to one or more embodiments.

FIG. 7 shows the depth map used for 2D modeling, according to one or more embodiments.

FIG. 8 shows a predicted porosity map of the area of interest of the reservoir, according to one or more embodiments.

FIG. 9 shows a predicted permeability map of the area of interest of the reservoir, according to one or more embodiments.

FIG. 10 shows the predicted residual porosity map caused by compaction, according to one or more embodiments.

FIG. 11 shows a map of the predicted decreased porosity caused by quartz cementation, according to one or more embodiments.

FIG. 12 shows a flowchart of the method steps for predicting a quality of a reservoir with 1D and 2D input data, according to one or more embodiments.

FIG. 13 illustrates the computer for performing the method steps for predicting a quality of a reservoir, according to one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Embodiments disclosed herein relate to a method for predicting a quality of a reservoir, comprising the steps: acquiring 1D input data comprising: depositional temperature and burial depth as function of a depositional time, and facies data and compaction data, adding a time interval to the depositional time, entering the 1D input data in a diagenesis model, wherein the diagenesis model comprises a compaction model that outputs a predicted compaction at a depositional time, and a cementation model that outputs a predicted cementation at the depositional time, repeating the previous two steps until the depositional time is the present time, and the diagenesis model outputs a predicted porosity curve, a predicted permeability curve, a predicted compacted porosity curve, and a predicted cement curve, as function of depth.

In another aspect, embodiments disclosed herein relate to a method for predicting a quality of a reservoir, comprising the steps: acquiring 2D input data comprising a depth map, and a facies map, at a depositional time, adding a time interval to the depositional time, entering the 2D input data in a diagenesis model, wherein the diagenesis model comprises a compaction model that outputs a predicted compaction at a depositional time, and a cementation model that outputs a predicted cementation at the depositional time, repeating the previous two steps until the depositional time is the present time, and the diagenesis model outputs a predicted porosity map, a predicted permeability map, a predicted compacted porosity map, and a predicted cement map.

Embodiments of the present disclosure may provide at least one of the following advantages. The method for predicting the reservoir quality is an advanced method to determine evolution history of clastic rocks considering the cumulative influence of compaction and quartz cementation. Based on sedimentary facies and burial depth, the method provides the reservoir porosity after compaction, the volumes of quartz cement, and final porosity, and permeability of the target reservoir from initial deposition to the burial depth at the present day. The predicted porosity and permeability are used as indicators for the non-reservoir, fair reservoir, and good reservoir, which facilitates the stratigraphic trap (sealed geologic container for retaining hydrocarbons) or diagenetic identification in the clastic reservoirs of interest.

The method for predicting the reservoir quality is used to assess the reservoir quality of clastic reservoirs with limited sample data comprising well burial and temperature history data, 2D facies and depth maps, and thus acts as an aid for assessing the economic viability of potential hydrocarbon reservoirs in frontier areas. The method for predicting the reservoir quality improves the understanding of the reservoir distribution in the area of interest. For example, high porosity areas develop a good reservoir quality and low porosity areas develop non-reservoir or a lateral seal.

The 1D diagenesis model simplifies the prediction, because only sedimentary facies, thermal history and burial depth are needed to obtain reservoir quality at a location of an area of interest.

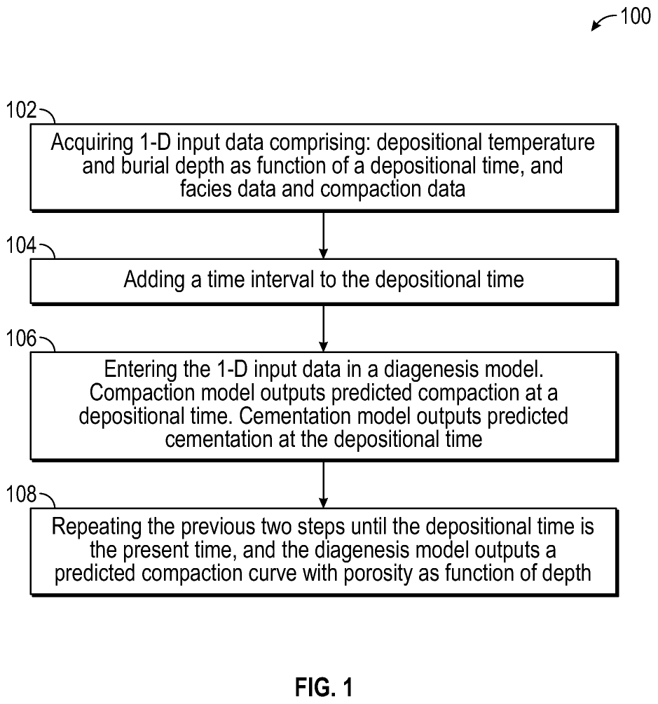

FIG. 1 shows a flowchart 100 of the method steps for predicting a quality of a reservoir with 1D input data.

In step 102, 1D input data comprising: depositional temperature and burial depth as function of a depositional time, and facies data and compaction data are acquired.

The diagenesis model requires two kinds of 1D input data. The first kind is depositional temperature and burial depth and the second kind is facies (characteristics of a rock that distinguishes it from adjacent rock) and compaction data. The 1D input data are stored in excel sheets and are entered separately.

Table 1 lists the thermal history (dispositional temperature) and the burial depth of a well as function of the depositional time. In one or more embodiments, burial and thermal history curves are acquired from the well. In other embodiments, burial and thermal history curves are obtained from basin modeling. Table 1 is entered in the diagenesis model to predict the evolution of the reservoir quality.

TABLE 1
1D input data comprising
burial and thermal history.

| Depositional | Depositional | Burial |
|---|---|---|
| Time in | Temperature | Depth |
| Million years | in ° C. | in ft |
| 274 | 3.11 | 0.00 |
| 273 | 17.78 | 160.60 |
| 269 | 22.02 | 255.77 |
| 264 | 32.76 | 1225.04 |
| 238 | 40.43 | 2130.93 |
| 231 | 45.10 | 3003.69 |
| 223 | 49.68 | 3872.46 |
| 211 | 54.19 | 4735.08 |
| 181 | 55.50 | 5035.92 |
| 179 | 56.58 | 5335.84 |
| 176 | 57.61 | 5634.94 |
| 160 | 64.77 | 6298.19 |
| 146 | 71.73 | 6933.82 |
| 131 | 78.15 | 7662.92 |
| 127 | 83.16 | 8114.31 |
| 124 | 88.92 | 9084.31 |
| 120 | 88.87 | 9358.97 |
| 115 | 94.47 | 10062.50 |
| 110 | 104.98 | 11025.20 |
| 97 | 113.34 | 11939.90 |
| 84 | 122.51 | 13054.50 |
| 71 | 123.87 | 13229.70 |
| 57 | 122.54 | 12980.20 |
| 44 | 126.78 | 13607.80 |
| 41 | 129.39 | 14109.90 |
| 37 | 129.42 | 14109.90 |
| 34 | 131.39 | 14254.20 |
| 30 | 136.21 | 14841.90 |
| 26 | 130.46 | 14043.70 |
| 21 | 127.76 | 13856.90 |
| 0 | 127.46 | 13856.90 |

Depositional time is the time of burial in million years, depositional temperature is the temperature of the burial in ° C., burial depth is the depth of burial in ft. From top to bottom, the depositional time is from the initial sedimentary period 274 million years ago until the present day (depositional time 0 years).

The 1D input data in table 1 shows that a piece of rock at the surface of the reservoir (burial depth 0 ft.) had a temperature of 3.11° C., 274 million years ago. One million year later (273 million years ago) the same piece of rock is buried at a burial depth of 160.60 ft and has a temperature of 17.78° C. The sample well according to table 1 has an initial time of 274 million years, a temperature of 3.11° C., and a depth of 0 ft. The sample well according to table 1 has at the present time (0 years) a temperature of 127.46° C. and a depth of 13856.9 ft. Table 1 is comprised in an excel sheet. The 1D input data in table 1 is obtained from basin modeling or geological reconstruction. The burial and thermal history evolution of an area of interest are expressed as the evolution of a well, because the reconstruction of these history curves is estimated using the present formation thickness and deposition age by a studied well.

Table 2 lists the facies and compaction data. The facies data is used for the quartz cementation model and the compaction data is used for the compaction model.

TABLE 2
1D input data comprising facies data and compaction data.

| | | | | Initial | | Initial | | |
|---|---|---|---|---|---|---|---|---|
| | | | | Por | | Por | | |
| Facies | V_{qtz} | Coat | D | Upper | aUpper | Lower | aLower | InitialPer |
| Dunes | 0.649 | 0 | 0.036 | 40.20 | −0.00006291 | 29.00 | −0.00001376 | 57000 |
| Interdune | 0.612 | 0 | 0.015 | 35.65 | −0.00008000 | 24.00 | −0.00002200 | 9400 |
| Playa | 0.669 | 0 | 0.023 | 33.08 | −0.00018000 | 27.00 | −0.00015000 | 35000 |
| Ephemeral | 0.691 | 0 | 0.022 | 38.00 | −0.00006875 | 27.00 | −0.00002000 | 19000 |
| channels | | | | | | | | |
| Fluvial | 0.601 | 0 | 0.021 | 37.44 | −0.00006500 | 27.00 | −0.00001400 | 19000 |
| flood | | | | | | | | |
| reworked | | | | | | | | |
| aeolian | | | | | | | | |

V_{qtz} is the abundance of quartz grains in initial sediment (fraction), coatis the surface area of the quartz that is coated (fraction), D is the average diameter of initial quartz grains, initialPorUpper and initialPorLower are the compacted porosity pre-exponential constant (%) in the upper and lower depth sections, and aUpper and aLower are the compacted porosity exponential constant in the upper and lower depth sections, initialPer is the permeability in mD.

In step 104, a time interval is added to the depositional time. In one or more embodiments, the time interval is 1 million years.

In step 106, the 1D input data is entered in a diagenesis model, wherein the diagenesis model comprises a compaction model that outputs a predicted compaction at a depositional time, and a cementation model that outputs a predicted cementation at the depositional time.

### 1D Diagenesis Model

The 1D diagenesis model comprises diagenetic compaction and cementation modeling. The 1D diagenesis model requires facies data, compaction data, burial data, and the thermal history as input data. In one or more embodiments, the facies data is embedded in the diagenesis model. Only the parameters of the diagenesis model are revised (calibration). When running the 1D diagenesis model, the input data needs to be entered and the target well and the facies of the area of interest need to be chosen.

Taking an example well with the dune facies, the running process of 1D modeling comprises compaction and quartz cementation modeling. The modeling is calculated from the initial deposition to the present day.

Its initial time is 274 million years, the initial temperature is 3.11° C. Its calculated compacted porosity is 40.2%, and quartz and illite cements are at 0%. After a while, the compacted and final porosities decrease and the cements increase.

At the present time, the burial depth is 13856.9 ft. and the temperature is 127.46° C. The predicted compacted porosity is 23.96%, quartz cement is 8.08%, and illite cements is 2.02%. The final porosity is 13.85% and permeability is 998.30 mD.

### Compaction Model

A compaction model calculates the residual porosity caused by compaction as a function of the depth (compaction curve). Considering the different porosity-depth gradient in different depth intervals, the compaction curve is separated into 2 equations at 2 km depth:

$${ϕ}_{com \_ final , f} = {ϕ}_{0 , f} - {ϕ}_{compaction , f}$$

$${ϕ}_{com \_ final \_ upper , f} = {A}_{f} {e}^{{a}_{f} z} for z < 2 km ( 6561.68 ft )$$

$${ϕ}_{com \_ final \_ lower , f} = {B}_{f} {e}^{{b}_{f} z} for z \geq 2 km ( 6561.68 ft )$$

where ϕ_{com_final,f} is the facies dependent residual porosity caused by compaction in %, ϕ_{0,f} is the initial porosity from the facies f in the depositional period in %, ϕ_{compaction,f} is the reduced porosity caused by compaction compaction, in %, ϕ_{com_final_upper,f} is the facies dependent residual porosity for a depth of less than 2 km, ϕ_{com_final_lower,f} is the facies dependent residual porosity for a depth of more than 2 km, A_{f} and B_{f} are the compacted porosity pre-exponential constant in %, a_{f} and b_{f} are the compacted porosity exponential constant, and z is the burial depth in ft.

The parameters A_{f}, B_{f}, a_{f}, and b_{f} are also controlled by sedimentary facies, which can be estimated from least-squares regression methods. Due to the influence of sedimentary facies on compaction, this approach requires to assign compaction curves for each sedimentary facies.

Consolidated sediments are sediments that are compacted and cemented until the sediment is solid. Consolidation leads to an increase in density and decrease in porosity. The porosity of sandstone (percentage of pore volume or void space, or that volume within rock that can contain fluids) decreases with increasing depth in shallow depths, which is mainly caused by the effective stress (mechanical compaction). Mechanical compaction is the physical process by which sediments are consolidated, resulting in the reduction of pore space as grains are packed closer together.

Increasing overburden pressure on the sediments during burial causes compaction of the sediment, loss of pore fluids and formation of rock as grains are cemented together, and layers of the sediment accumulate. Compaction consolidates the sediment and reduces the pore space of the sediment, as grains of the sediment are packed closer together. Cementation is a process to carry ions in groundwater, wherein the ions chemically precipitate to form a crystalline material between grains of the sediment. The crystalline material fills the pores of minerals and forms “bridges” between original sediment grains to bind the grains together. In this way, sand becomes sandstone. Sandstone is clastic sedimentary rock (sediment comprising broken fragments) with grains that are predominantly the size of sand. Sandstone comprises consolidated sand (compacted and cemented sediments such that they become coherent like solid rock) or a rock made of predominantly quartz sand (abundant rock-forming mineral composed of silicon and oxygen SiO2). Cementation occurs as part of the diagenesis or lithification of sediments. Diagenesis is the physical, chemical, or biological alteration of sediments into sedimentary rock at relatively low temperatures and pressures that results in changes to the original mineralogy and texture of the rock.

The compaction curve is expressible as an exponential relationship between porosity and depth. The reduction of reservoir porosity at a depth less than 2 km (6561.68 ft) is steady, which is mainly controlled by mechanical compaction. In contrast, the porosity drops notably at the depth deeper than 2 km (6561.68 ft), which is controlled by complex diagenesis such as quartz cementation. The degree of compaction is also influenced by sedimentary facies such as textural and compositional attributes.

### Cementation Model

Quartz is a rock-forming mineral composed of silicon and oxygen (silica). Sand grains comprising quartz are comprised in sandstone and other clastic sedimentary rocks. A cementation model calculates the residual porosity caused by quartz cementation.

The quartz cementation is an important process of porosity reduction in a clastic reservoir. The precipitation of quartz cementation occurs after effective burial and compaction above about 80° C., because temperature controls the solubility of quartz and the most important SiO₂-liberating reactions. Quartz cement often occurs as quartz overgrowths or pore-filling microcrystalline quartz and occupies the reservoir pores.

For the method for predicting the reservoir quality, the prediction process of clastic rock reservoir quality comprises the following steps:

The method for predicting the reservoir quality uses a kinetical-controlled quartz cementation model from Lander and Walderhaug (1999). The quartz cementation model is revised based on sedimentary facies, which means the input data vary for different facies. The revised function calculates the total amount of quartz cement precipitated during an increment in time by considering the available surface area of the quartz in the sandstone for precipitation of quartz cement, and by considering the temperature range experienced by the clastic reservoir interval of interest:

$${ϕ}_{cementation , f} = \frac{m}{ρ} {A}_{t , f} a {\int }_{0}^{t} {e}^{\frac{- Ea}{{RT}_{t}}} dt ,$$

where ϕ_{cementation , f} is the facies dependent volume of quartz that precipitates for the present time step in cm³, m is the molar weight of quartz (60.08 g/mol), ρ is the density of quartz (2.65 g/cm³), A_{t,f} is the surface area of the quartz for the present time step in cm², a is the quartz precipitation rate pre-exponential constant in mol/cm²·s,t is the duration of the time step in million years, Ea is activation energy of quartz in kcal/mole, R is gas constant, and Tₜ is the temperature ° C.

The surface area of the quartz is an important factor controlling the net rate of quartz cementation. It is a function of the abundance of detrital quartz grains in the initial sediment, the average quartz grain size, and the porosity through time:

$${A}_{t , f} = ( 1 - {coat}_{f} ) [ \frac{6 {V}_{qtz , f} {v}_{0 , f}}{{D}_{f}} ( \frac{{ϕ}_{final , t}}{{ϕ}_{0 , f}} ) ] ,$$

where V_{qtz,f} is the facies dependent abundance of quartz grains in the initial sediment(fraction), v_{0,f} is the initial rock volume in cm³, D_{f} is the average diameter of initial quartz grains from facies f in cm, ϕ_{final ,t} is the porosity for the present time step in %, ϕ_{0,f} is the initial porosity from facies f in %, and coat_{f} is the facies dependent surface area of the quartz that is coated (fraction). The detailed parameter values are mainly obtained from petrological study.

The 1D diageneses model separates the compaction model from the cementation model. The compaction model and the cementation model are controlled by the sedimentary facies.

In step 108, the previous two steps are repeated until the depositional time is the present time, and the diagenesis model outputs a predicted compaction curve with porosity as function of depth.

### 1D Data Output

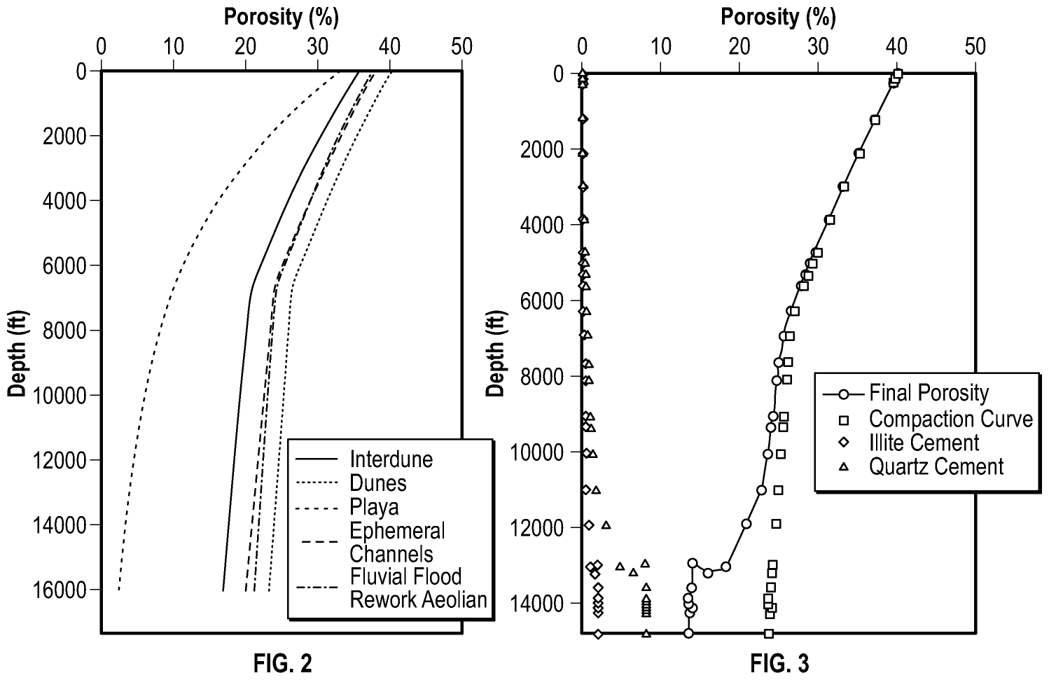

FIG. 2 shows porosities of facies as a function of the depth of the facies (compaction curves) of five types of sedimentary facies, according to one or more embodiments. The five facies are Dunes, Interdune, Playa, ephemeral channels, and fluvial flood reworked aeolian. The compaction curves in FIG. 2 illustrate the effects of burial history on the porosity of compacted sediment. The compaction curves are exponential function.

FIG. 3 shows predicted curves for compacted porosity, quartz cement, illite cement, final porosity with burial depth of the target well.

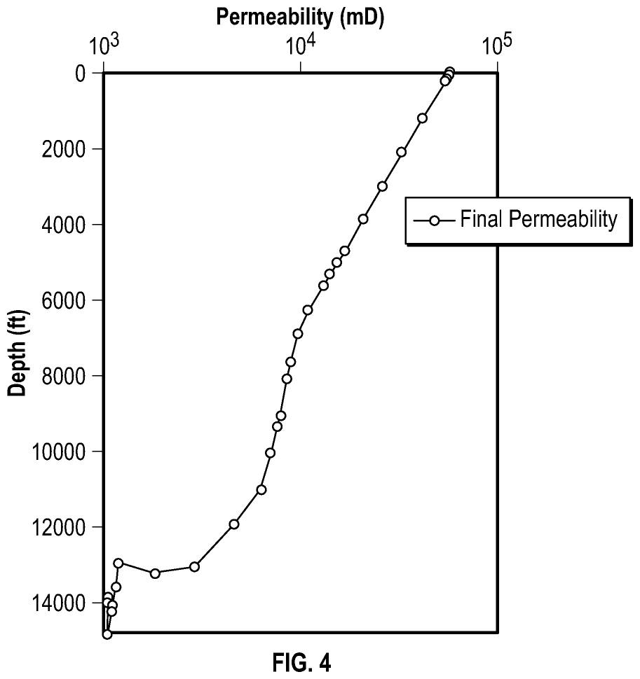

FIG. 4 shows the permeability variation with burial depth of a sample well with dunes as the facies.

TABLE 3
1D output data of a sample well

| | | | | React | | | | |
|---|---|---|---|---|---|---|---|---|
| | | | Poro | Surface | Quartz | Illite | Poro | Perm |
| Time | Temp | Depth | Mech | Area | Cement | Cement | Final | Final |
| 274 | 3.11 | 0.00 | 40.20 | 108.200 | 0.0000 | 0.0000 | 40.20 | 57000.00 |
| 273 | 17.78 | 160.60 | 39.80 | 104.058 | 0.0002 | 0.0001 | 39.80 | 54556.67 |
| 269 | 22.02 | 255.77 | 39.56 | 103.012 | 0.0019 | 0.0005 | 39.56 | 53152.79 |
| 264 | 32.76 | 1225.04 | 37.22 | 102.391 | 0.0063 | 0.0016 | 37.21 | 41002.89 |
| 238 | 40.43 | 2130.93 | 35.16 | 96.320 | 0.0494 | 0.0123 | 35.09 | 32192.96 |
| 231 | 45.10 | 3003.69 | 33.28 | 90.843 | 0.0666 | 0.0167 | 33.19 | 25715.22 |
| 223 | 49.68 | 3872.46 | 31.51 | 85.925 | 0.0929 | 0.0232 | 31.39 | 20620.51 |
| 211 | 54.19 | 4735.08 | 29.84 | 81.258 | 0.1450 | 0.0363 | 29.66 | 16551.82 |
| 181 | 55.50 | 5035.92 | 29.28 | 76.782 | 0.2946 | 0.0736 | 28.92 | 15013.07 |
| 179 | 56.58 | 5335.84 | 28.74 | 74.850 | 0.3051 | 0.0763 | 28.36 | 13936.19 |
| 176 | 57.61 | 5634.94 | 28.20 | 73.399 | 0.3217 | 0.0804 | 27.80 | 12930.01 |
| 160 | 64.77 | 6298.19 | 27.05 | 71.958 | 0.4403 | 0.1101 | 26.50 | 10805.73 |
| 146 | 71.73 | 6933.82 | 26.36 | 68.591 | 0.5976 | 0.1494 | 25.61 | 9528.10 |
| 131 | 78.15 | 7662.92 | 26.10 | 66.301 | 0.8454 | 0.2113 | 25.04 | 8767.38 |
| 127 | 83.16 | 8114.31 | 25.94 | 64.818 | 0.9359 | 0.2340 | 24.77 | 8420.13 |
| 124 | 88.92 | 9084.31 | 25.59 | 64.106 | 1.0285 | 0.2571 | 24.31 | 7863.46 |
| 120 | 88.87 | 9358.97 | 25.50 | 62.916 | 1.1695 | 0.2924 | 24.03 | 7547.20 |
| 115 | 94.47 | 10062.50 | 25.25 | 62.210 | 1.3751 | 0.3438 | 23.53 | 6990.55 |
| 110 | 104.98 | 11025.20 | 24.92 | 60.909 | 1.6968 | 0.4242 | 22.80 | 6235.77 |
| 97 | 113.34 | 11939.90 | 24.61 | 59.008 | 3.0008 | 0.7502 | 20.85 | 4542.83 |
| 84 | 122.51 | 13054.50 | 24.23 | 53.982 | 4.7620 | 1.1905 | 18.28 | 2868.95 |
| 71 | 123.87 | 13229.70 | 24.17 | 47.313 | 6.5546 | 1.6386 | 15.98 | 1813.34 |
| 57 | 122.54 | 12980.20 | 24.26 | 41.362 | 8.0892 | 2.0223 | 14.14 | 1204.38 |
| 44 | 126.78 | 13607.80 | 24.05 | 0.000 | 8.0892 | 2.0223 | 13.94 | 1146.30 |
| 41 | 129.39 | 14109.90 | 23.88 | 0.000 | 8.0892 | 2.0223 | 13.77 | 1101.67 |
| 37 | 129.42 | 14109.90 | 23.88 | 0.000 | 8.0892 | 2.0223 | 13.77 | 1101.67 |
| 34 | 131.39 | 14254.20 | 23.83 | 0.000 | 8.0892 | 2.0223 | 13.72 | 1089.14 |
| 30 | 136.21 | 14841.90 | 23.64 | 0.000 | 8.0892 | 2.0223 | 13.53 | 1039.42 |
| 26 | 130.46 | 14043.70 | 23.90 | 0.000 | 8.0892 | 2.0223 | 13.79 | 1107.46 |
| 21 | 127.76 | 13856.90 | 23.96 | 0.000 | 8.0892 | 2.0223 | 13.85 | 1123.96 |
| 0 | 127.46 | 13856.90 | 23.96 | 0.000 | 8.0892 | 2.0223 | 13.85 | 1123.96 |

Table 3 lists the 1D output data. Referring to Table 3, Time represents the depositional time in million years, Temp is the depositional temperature in ° C., Depth is the burial depth in ft., PoroMech is the compacted porosity in %, React Surface Area is the effective reaction surface area, Quartz Cement is the volume of the quartz cement in %, Illite Cement is the volume of illite cement in %, Poro Final is the final porosity in % with each depositional time from initial time to present, and Perm Final is the final permeability in %.

### Final Output: Reservoir Quality

The reservoir quality of a clastic reservoir is a cumulative product of depositional and diagenetic processes. The initial reservoir quality is primarily controlled by depositional environment. The reduction of original porosity and permeability occurs due to early mechanical compaction and then followed by cementation and further compaction. The reservoir porosity can be calculated as follows:

$${ϕ}_{final} = {ϕ}_{0 , f} - {ϕ}_{compaction , f} - {ϕ}_{cementation , f} ,$$

wherein ϕ_{final} is the final porosity in %. The final porosity ϕ_{final} can also be expressed as:

$${ϕ}_{final} = {ϕ}_{com \_ final , f} - {ϕ}_{cementation , f}$$

The calculation of matrix permeability follows the Kozeny-Carman equation. Its value is calculated from porosity ignoring changes in grain size, tortuosity and specific surface area as follows:

$$k = {k}_{0 , f} \frac{{( 1 - {ϕ}_{0 , f} )}^{2}}{{( 1 - ϕ )}^{2}} {( \frac{ϕ}{{ϕ}_{0 , f}} )}^{3} ,$$

wherein k is the reservoir porosity in %, ϕ is the permeability in mD, k_{0,f} is the initial permeability in mD from facies f.

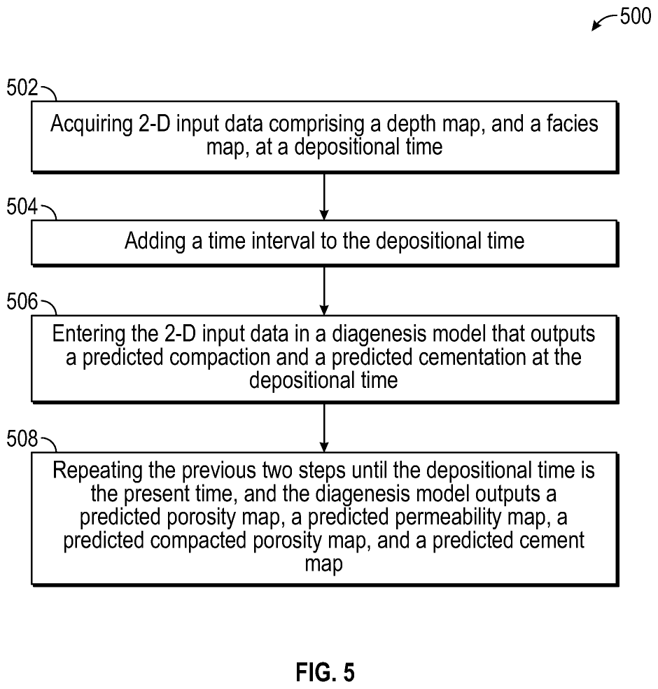

FIG. 5 shows a flowchart 500 of the method steps for predicting a quality of a reservoir with 2D input data.

In step 502, 2D input data comprising a depth map, and a facies map, at a depositional time are acquired. In one or more embodiments, the depositional time is the present time.

### 2D Input Data

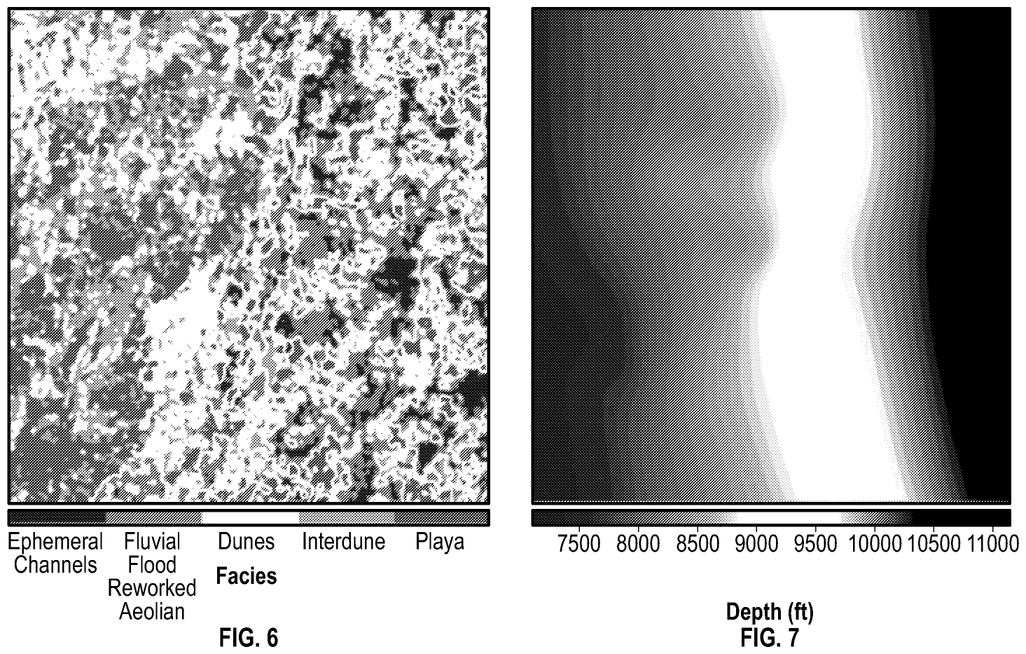

For a 2D diagenetic modeling a facies map and a burial depth map of the area of interest of the reservoir are required as input data to the 2D diagenesis model. FIGS. 6 and 7 show 2D input data that are entered in the diagenesis model.

FIG. 6 shows the sedimentary facies map at the present time used for 2D modeling. The calculated final reservoir quality is calibrated by the measured data from the wells. The sedimentary facies map shows the area of interest of the reservoir, wherein different partial areas in the area of interest show different colors. The colors comprise orange, yellow, green, light blue, and dark blue. Each color represents a facies. Orange represents ephemeral channels, yellow represents fluvial flood reworked aeolian, green represents dunes, dark blue represents interdune, and dark blue represents playa. FIG. 6 shows the distribution of the facies in the area of interest.

Table 4 lists the data of the facies map of FIG. 6, according to the fluvial-aeolian depositional system.

TABLE 4
2D input data of the facies
map of FIG. 6 at the present
time, according to the fluvial-
aeoliandepositional system.

| X | Y | facies |
|---|---|---|
| 741800 | 2606700 | 5 |
| 741800 | 2606800 | 5 |
| 741800 | 2606900 | 5 |
| 741800 | 2607000 | 5 |
| 741800 | 2607100 | 4 |
| 741800 | 2607200 | 4 |
| 741800 | 2607300 | 3 |
| 741800 | 2607400 | 3 |
| 741800 | 2607500 | 3 |
| 741800 | 2607600 | 3 |
| 741800 | 2607700 | 3 |
| 741800 | 2607800 | 3 |
| 741800 | 2607900 | 3 |
| 741800 | 2608000 | 3 |
| 741800 | 2608100 | 3 |
| 741800 | 2608200 | 3 |
| 741800 | 2608300 | 4 |
| 741800 | 2608400 | 4 |
| 741800 | 2608500 | 4 |
| 741800 | 2608600 | 4 |
| 741800 | 2608700 | 4 |
| 741800 | 2608800 | 4 |
| 741800 | 2608900 | 4 |
| 741800 | 2609000 | 3 |
| 741800 | 2609100 | 3 |
| 741800 | 2609200 | 3 |
| 741800 | 2609300 | 3 |
| 741800 | 2609400 | 3 |
| 741800 | 2609500 | 3 |
| 741800 | 2609600 | 3 |
| 741800 | 2609700 | 3 |
| 741800 | 2609800 | 3 |

Table 4 lists the data for a small part of the map. The X- and Y-values of the map are imaged as the longitude and latitude of an area of interest. Thus, the data indicates a latitude line of the area of interest with change of latitude and without change of longitude.

The first column in Table 4 represents the x-axis of the facies map in FIG. 6, the second column in table 4 represents the y-axis of the facies map in FIG. 6, and the third column represents facies type according to the colors in the facies map of FIG. 6. Taking the fluvial-aeoliandepositional system as an example, 1 is the ephemeral channels, 2 is the fluvial flood reworked aeolian facies, 3 is the dunes, 4 is the interdune, and 5 is the playa.

Each row represents each grid (a series of vertical cross-sections extracted from a 3D seismic data volume) of an area of interest, which is also the seismic coordinate of a seismic node from seismic data. During seismic data acquisition, cable systems offer a real-time access to the seismic data during source production, since all acquisition units are interconnected, ultimately delivering data directly to a central computer system. The nodes are autonomous acquisition units with no interconnectivity. The data volume comprising X, Y, and seismic attributes of each grid are obtained from seismic interpretation. The x- and y-coordinates and types of facies of each gird are obtained from seismic data. The facies types are defined from geological analysis and seismic interpretation. The grids are discretization of a 3D seismic volume. Each grid is defined as a position to each node position of the seismic data acquisition system.

FIG. 7 shows the depth map used for 2D modeling. FIG. 7 shows a map of an area of interest on the surface of the reservoir. The area of interest comprises pixels with a color that varies between dark blue and dark red. The color indicates the burial depth in feet (ft.) of a piece of rock. A dark blue pixel represents a burial depth of 7,000 ft. and a dark red pixel represent a burial depth of more than 11,000 ft. FIG. 7 shows the burial depth of each partial area within the area of interest.

Table 5 contains 2D depth data of FIG. 7. Each row represents each grid similar to table 4. The order of columns from left to right is X-coordinate, Y-coordinate, and the burial depth in ft at the present time. The present burial depth of each gird is also obtained from seismic data.

TABLE 5
2D input data of
the depth map of FIG. 7.

| X | Y | depth |
|---|---|---|
| 741800 | 2601200 | 7106.811 |
| 741900 | 2601200 | 7113.337 |
| 742000 | 2601200 | 7119.864 |
| 742100 | 2601200 | 7126.391 |
| 742200 | 2601200 | 7132.918 |
| 742300 | 2601200 | 7139.447 |
| 742400 | 2601200 | 7145.976 |
| 742500 | 2601200 | 7152.505 |
| 742600 | 2601200 | 7159.036 |
| 742700 | 2601200 | 7165.567 |
| 742800 | 2601200 | 7172.1 |
| 742900 | 2601200 | 7178.634 |
| 743000 | 2601200 | 7185.169 |
| 743100 | 2601200 | 7191.706 |
| 743200 | 2601200 | 7198.245 |
| 743300 | 2601200 | 7204.785 |
| 743400 | 2601200 | 7211.327 |
| 743500 | 2601200 | 7217.872 |
| 743600 | 2601200 | 7224.418 |
| 743700 | 2601200 | 7230.968 |
| 743800 | 2601200 | 7237.521 |
| 743900 | 2601200 | 7244.076 |
| 744000 | 2601200 | 7250.634 |
| 744100 | 2601200 | 7257.196 |
| 744200 | 2601200 | 7263.762 |
| 744300 | 2601200 | 7270.332 |
| 744400 | 2601200 | 7276.905 |
| 744500 | 2601200 | 7283.483 |
| 744600 | 2601200 | 7290.066 |
| 744700 | 2601200 | 7296.653 |
| 744800 | 2601200 | 7303.246 |
| 744900 | 2601200 | 7309.844 |

Returning to the flowchart of FIG. 5, in Step 504, a time interval is added to a depositional time.

In Step 506, the 2D input data are entered in a 2D diagenesis model that outputs a predicted compaction and a predicted cementation at the depositional time.

The 2D diagenesis model needs facies and depth maps of the area of interest at the present time. The 2D diagenesis model is separated into two parts. The first part is to restore the burial history of the input data, calculating the burial, thermal, and depth of each grid, through horizontal refraction from the standard well.

In a formation, the burial history evolution of each depth point is similar, rising or dropping at the same historical time. When a well depth data is known, a mathematic method, such as horizontal refraction is used to calculate the depth data of other depth points in the area of interest, which means the whole 2D data is obtainable.

The second part is to calculate diagenetic modeling of each grid with the 1D diagenesis model. After 1D modeling, the values for porosity, permeability, quartz cement, and illite cement from initial deposition time to the present day of each grid are calculated and then the maps are generated. For example, maps of compaction, cement, final porosity, permeability distribution, and cement in the reservoir of interest are generated.

In Step 508, the previous two steps are repeated until the depositional time is the present time, and the diagenesis model outputs a predicted porosity map, a predicted permeability map, a predicted compacted porosity map, and a predicted cement map.

### 2D Outputdata

FIG. 8 shows a predicted porosity map of the area of interest of the reservoir. In particular, FIG. 8 shows the area of interest with different partial areas in different colors. The colors vary between dark blue and dark red and represent different porosities in %. Dark blue represents a partial area of 2% porosity, whereas dark red represents a partial area of 20% porosity. The porosity map is predicted by the diagenesis model.

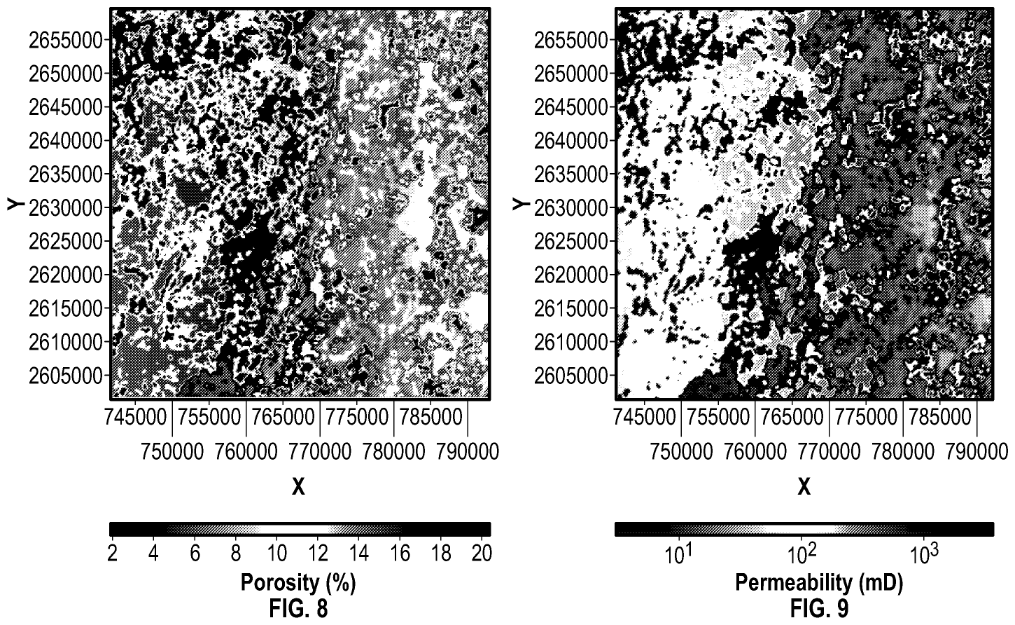

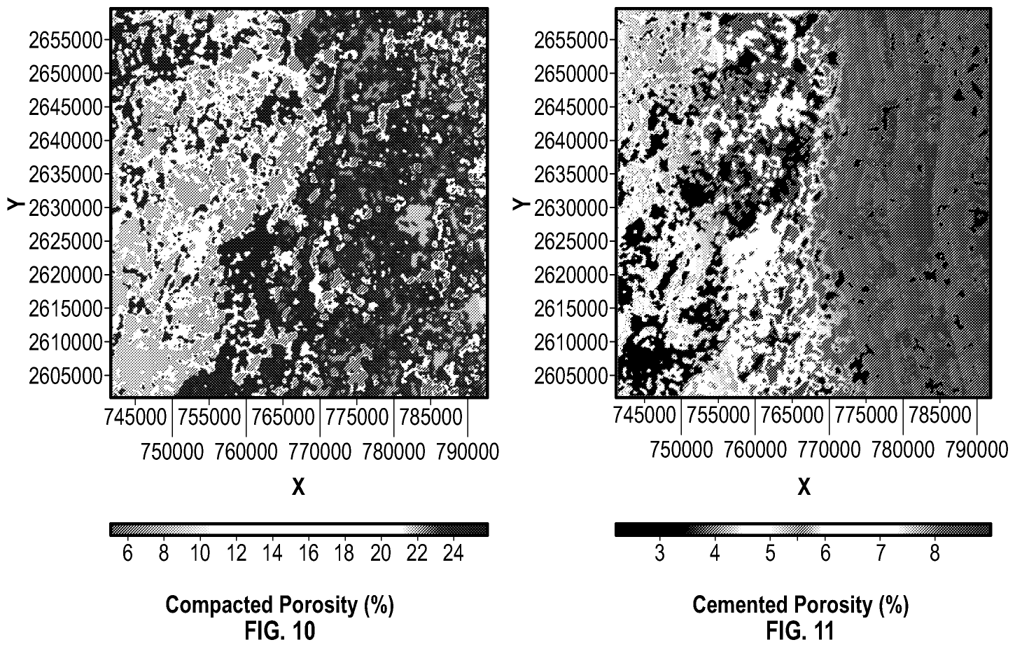

FIG. 9 shows a predicted permeability map of the area of interest of the reservoir. In particular, FIG. 9 shows the area of interest with different partial areas in different colors. The colors vary between dark blue and dark red and represent different permeabilities in mD. Dark blue represents a partial area with a permeability of 1 mD, whereas dark red represents a partial area with a permeability of 10,000 mD. The permeability map is predicted by the diagenesis model.

FIG. 10 shows the predicted residual porosity map (ϕ₀-ϕ_{final,t}) caused by compaction (compacted porosity). The compacted porosity map comprises partial areas ranging from 5 to 26% porosity. Each partial area has a different color according to the porosity of the partial area. The colors of the partial areas range from dark blue (5% porosity) to dark red (26% porosity).

FIG. 11 shows a map of the predicted decreased porosity ϕ_{cementation ,f} caused by quartz cementation (cemented porosity). The cemented porosity map comprises partial areas ranging from 2 to 9% porosity. Each partial area has a different color according to the porosity of the partial area. The colors of the partial areas range from dark blue (2% porosity) to dark red (9% porosity).

TABLE 6
2D output data of an area of interest

| | | Facies | Present | | | Quartz | Illite |
|---|---|---|---|---|---|---|---|
| X | Y | index | Depth | Porosity | Permeability | Cement | Cement |
| 741800 | 2601200 | 4 | 7106.8105 | 13.8959 | 310.9281 | 7.0966 | 1.7742 |
| 741800 | 2601300 | 4 | 7107.5898 | 13.8941 | 310.7899 | 7.0979 | 1.7745 |
| 741800 | 2601400 | 5 | 7108.3687 | 4.5390 | 44.4339 | 1.4897 | 0.3724 |
| 741800 | 2601500 | 5 | 7109.1475 | 4.5377 | 44.3956 | 1.4898 | 0.3725 |
| 741800 | 2601600 | 5 | 7109.9268 | 4.5365 | 44.3573 | 1.4899 | 0.3725 |
| 741800 | 2601700 | 5 | 7110.7061 | 4.5352 | 44.3190 | 1.4900 | 0.3725 |
| 741800 | 2601800 | 5 | 7111.4849 | 4.5339 | 44.2808 | 1.4901 | 0.3725 |
| 741800 | 2601900 | 5 | 7112.2642 | 4.5327 | 44.2426 | 1.4902 | 0.3725 |
| 741800 | 2602000 | 5 | 7113.0435 | 4.5314 | 44.2044 | 1.4903 | 0.3726 |
| 741800 | 2602100 | 5 | 7113.8223 | 4.5302 | 44.1662 | 1.4904 | 0.3726 |
| 741800 | 2602200 | 5 | 7114.6016 | 4.5289 | 44.1281 | 1.4905 | 0.3726 |
| 741800 | 2602300 | 5 | 7115.3809 | 4.5276 | 44.0900 | 1.4905 | 0.3726 |
| 741800 | 2602400 | 5 | 7116.1597 | 4.5264 | 44.0520 | 1.4906 | 0.3727 |
| 741800 | 2602500 | 5 | 7116.9390 | 4.5251 | 44.0140 | 1.4907 | 0.3727 |
| 741800 | 2602600 | 5 | 7117.7183 | 4.5238 | 43.9759 | 1.4908 | 0.3727 |
| 741800 | 2602700 | 5 | 7118.4971 | 4.5226 | 43.9380 | 1.4909 | 0.3727 |
| 741800 | 2602800 | 5 | 7119.2764 | 4.5213 | 43.9000 | 1.4910 | 0.3728 |
| 741800 | 2602900 | 5 | 7120.0552 | 4.5201 | 43.8622 | 1.4911 | 0.3728 |
| 741800 | 2603000 | 5 | 7120.8340 | 4.5188 | 43.8243 | 1.4912 | 0.3728 |
| 741800 | 2603100 | 5 | 7121.6128 | 4.5175 | 43.7865 | 1.4913 | 0.3728 |
| 741800 | 2603200 | 5 | 7122.3916 | 4.5163 | 43.7487 | 1.4914 | 0.3728 |
| 741800 | 2603300 | 5 | 7123.1699 | 4.5150 | 43.7109 | 1.4915 | 0.3729 |
| 741800 | 2603400 | 5 | 7123.9482 | 4.5138 | 43.6732 | 1.4916 | 0.3729 |
| 741800 | 2603500 | 5 | 7124.7261 | 4.5125 | 43.6355 | 1.4916 | 0.3729 |
| 741800 | 2603600 | 5 | 7125.5034 | 4.5112 | 43.5979 | 1.4917 | 0.3729 |
| 741800 | 2603700 | 5 | 7126.2803 | 4.5100 | 43.5603 | 1.4918 | 0.3730 |
| 741800 | 2603800 | 5 | 7127.0562 | 4.5087 | 43.5229 | 1.4919 | 0.3730 |
| 741800 | 2603900 | 5 | 7127.8320 | 4.5075 | 43.4854 | 1.4920 | 0.3730 |
| 741800 | 2604000 | 5 | 7128.6069 | 4.5062 | 43.4480 | 1.4921 | 0.3730 |
| 741800 | 2604100 | 5 | 7129.3809 | 4.5050 | 43.4107 | 1.4922 | 0.3730 |
| 741800 | 2604200 | 5 | 7130.1533 | 4.5037 | 43.3735 | 1.4923 | 0.3731 |
| 741800 | 2604300 | 5 | 7130.9253 | 4.5025 | 43.3364 | 1.4924 | 0.3731 |
| 741800 | 2604400 | 5 | 7131.6953 | 4.5012 | 43.2993 | 1.4925 | 0.3731 |
| 741800 | 2604500 | 5 | 7132.4644 | 4.5000 | 43.2624 | 1.4925 | 0.3731 |
| 741800 | 2604600 | 5 | 7133.2314 | 4.4987 | 43.2256 | 1.4926 | 0.3732 |

Table 6 lists the 2D output data. The columns of the exported 2D data are X-coordinate, Y-coordinate, facies code, present burial depth in ft., final compacted porosity in %, final porosity in %, final permeability in mD, the volumes of quartz cement in % and illite cement in % from left to right. Each row represents the data of each grid.

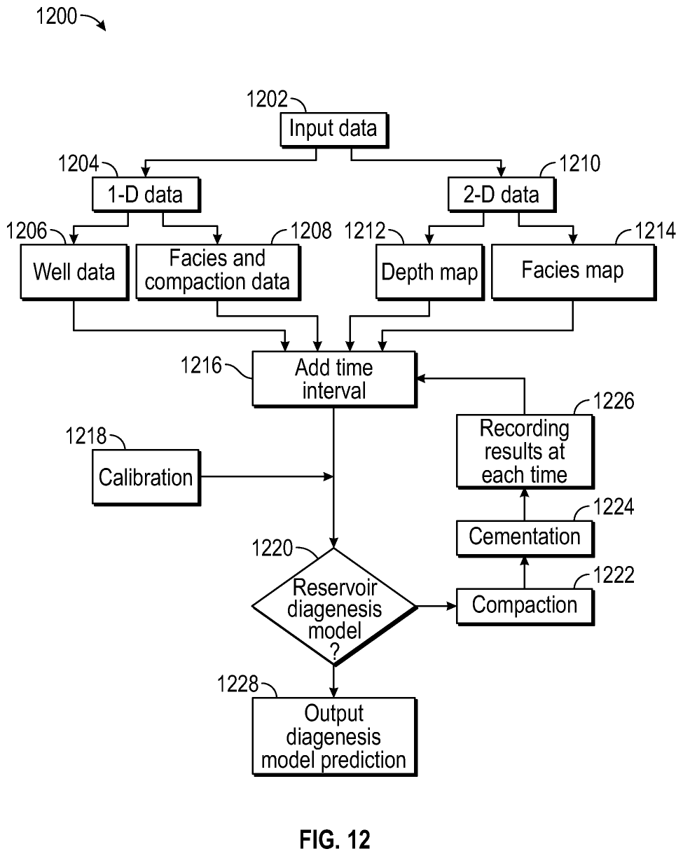

FIG. 12 shows a flowchart 1200 of the method steps for predicting a quality of a reservoir with 1D and 2D input data, according to one or more embodiments. The method for predicting the reservoir quality was tested on a typical well in the area of interest of a reservoir. The well provides cement, compaction, porosity, and permeability history evolution with time or depth that is used for the diagenesis model. 2D modeling are prone to show the predicted maps at a geological time. First of all, the input data are obtained from previous research data, basin modeling, etc. Then the input data are stored in separate excel files. The input data comprise burial depth, thermal history, facies and compaction data. In step 1202, the input data is acquired at a depositional time. The input data is one-dimensional (1D) 1204 or two-dimensional (2D) 1210. The 1D input data 1204 comprises burial depth and thermal history 1206 and sedimentary facies and compaction data 1208. The 2D input data 1210 comprises a depth map 1212 and a sedimentary facies map 1214.

In step 1216, a time interval is added to the depositional time. In one or more embodiments, the time interval is one million year. For example, when the depositional time is −274 million years (274 million years ago) and the time interval is one million year then the addition of the time interval leads to a depositional time of −273 million years.

Before the input data 1202 are entered in the diagenesis model 1220, the input data 1202 is calibrated.

In step 1218, the input data 1202 is calibrated. The calibration comprises adjusting the model parameters of the diagenesis model.

In step 1220, the input data 1202 is entered to the diagenesis model. In one or more embodiments, either the 1D input data or the 2D input data are entered to the diagenesis model 1220. In other embodiments, 1D data and the 2D data are entered simultaneously to the diagenesis model 1220.

In step 1222, the diagenesis model 1220 uses a compaction model to predict the compaction curve of the reservoir.

In step 1224, the diagenesis model 1220 uses a quartz cementation model to predict the cementation of the reservoir.

In step 1226, the prediction results of the diagenesis model 1220 are recorded. After the recordation of the prediction results, another time interval is added and the input data is calibrated again and entered into the diagenesis model 1220. In other words, after the step 1226, the steps 1216, 1218, and 1220 are repeated. Afterwards, the diagenesis model 1220 predicts the compaction 1222, the cementation 1224, and the recordation of data 1226. The steps 1220, 1222, 1224, 1226, 1216, 1218, and 1220 are repeated until the depositional time is the present (0 year).

In step 1228, the diagenesis model 1220 outputs modeling results. In case of 1D data the diagenesis model 1220 outputs a table. In case of 2D data the diagenesis model 1220 outputs a map.

In one or more embodiments, the steps of the flowchart 1200 run in parallel, in combination, in loops, or in any order.

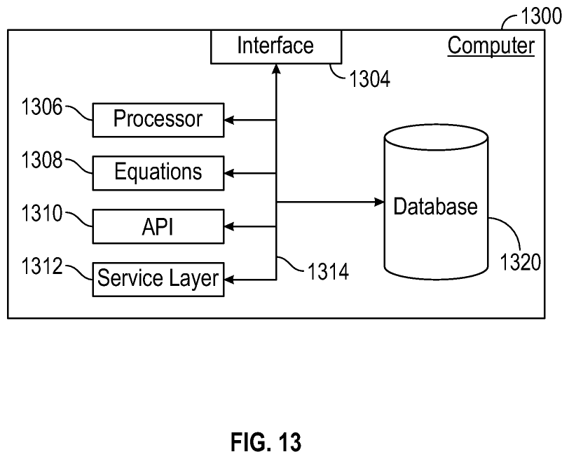

FIG. 13 illustrates a computer 1300 for performing the method steps for predicting a quality of a reservoir. In one or more embodiments, the computer 1300 is a high performance computing (HPC) device, server, desktop computer, laptop/notebook computer, wireless data port, smart phone, personal data assistant (PDA), tablet computing device, one or more computer processors within these devices, or any other suitable processing device, comprising both physical or virtual instances (or both) of the computing device. Additionally, the computer 1300 comprises an input device, such as a keypad, keyboard, touch screen, or other device that can accept user information, and an output device that conveys information associated with the operation of the computer 1300, comprising digital data, visual, or audio information (or a combination of information), or a GUI.

The computer 1300 comprises an interface 1304 that receives the input data. The interface 1304 comprises software supporting one or more communication protocols. The interface 1304 further comprises hardware that receives physical signals within and outside of the illustrated computer 1300.

Furthermore, the computer 1300 comprises a software component 1308 with equations for performing the method steps for predicting a quality of a reservoir. The equations are stored in the software component of the computer 1300. Although illustrated as an internal part of the computer 1300, in alternative embodiments, the software component 1308 are an external component of the computer 1300.

The computer 1300 comprises a processor 1306. The processor 1306 executes instructions according to the software component 1308 and manipulates the input data to perform the method steps for predicting a quality of a reservoir according to the software component 1308.

The computer 1300 further comprises a database 1320 for storing the output data. While the database 1320 is illustrated as an integral component of the computer 1300, in alternative embodiments, the database 1320 is external to the computer 1300. The database 1320 may be any repository capable of storing data, including but not limited to data structures such as tables, lists, arrays, etc.

The interface 1304, the processor 1306, the software component 1308, and the database 1320 communicate via a system bus 1314. In one or more embodiments, any or all of the interface 1304, the processor 1306, the software component 1308, and the database 1320, communicate with each other over the system bus 1314 using an application programming interface (API) 1310 or a service layer 1312 or a combination of the API 1310 and service layer 1312.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f) for any limitations of any of the claims herein, except for those in which the claim expressly uses the words ‘means for’ together with an associated function.

1. A method for predicting a quality of a reservoir, comprising the steps:
drilling a well that penetrates the reservoir,
acquiring one-dimensional (1D) input data from the well, wherein the input data comprise:
depositional temperature and burial depth as function of a depositional time, and
facies data and compaction data,
adding a time interval to the depositional time,
entering the 1D input data in a diagenesis model, wherein the diagenesis model comprises a compaction model that outputs a predicted compaction at a depositional time, and a cementation model that outputs a predicted cementation at the depositional time,
repeating the previous two steps until the depositional time is the present time, and the diagenesis model outputs a predicted compaction curve with porosity as function of depth.

2. The method according to claim 1, wherein the diagenesis model uses a compaction model with two equations to predict the compaction curve, wherein a first equation is for depths above 2 km (6561.68 ft) and a second equation is for depths below 2 km (6561.68 ft).

3. The method according to claim 2, wherein the first equation is an exponential relationship between porosity and depth.

4. The method according to claim 2, wherein first equation is controlled by mechanical compaction.

5. The method according to claim 2, wherein the second equation is an exponential relationship between porosity and depth.

6. The method according to claim 2, wherein the second equation is controlled by quartz cementation.

7. The method according to claim 1, wherein the cementation model comprises a kinetical-controlled quartz cementation model from Lander and Walderhaug.

8. The method according to claim 1, wherein the diagenesis model further outputs with each depositional time: compacted porosity, effective reaction surface area, volume of the quartz cement, volume of illite cement, final porosity, and final permeability.

9. The method according to claim 1, wherein the diagenesis model predicts the permeability by Kozeny-Carman equation.

10. The method according to claim 1, wherein the facies and compaction data comprise:
abundance of quartz grains in initial sediment,
surface area of the quartz coated,
average diameter of initial quartz grains,
compacted porosity pre-exponential constant in the upper depth section,
compacted porosity pre-exponential constant in the lower depth section,
compacted porosity exponential constant in the upper depth section,
compacted porosity exponential constant in the lower depth section, and
permeability.

11. The method according to claim 1, wherein the diagenesis model is calibrated by adjusting the parameters of the diagenesis model.

12. A method for predicting a quality of a reservoir, comprising the steps:
drilling a well that penetrates the reservoir,
acquiring 2D input data from the well and seismic interpretation, wherein the input data comprise a depth map, and a facies map, at the present time,
adding a time interval to the depositional time,
entering the 2D input data in a diagenesis model, wherein the diagenesis model comprises a compaction model that outputs a predicted compaction at a depositional time, and a cementation model that outputs a predicted cementation at the depositional time,
repeating the previous two steps until the depositional time is the present time, and the diagenesis model outputs a predicted porosity map, a predicted permeability map, a predicted compacted porosity map, and a predicted cement map.

13. The method according to claim 12, wherein the diagenesis model uses a compaction model with two equations to predict the compaction curve, wherein a first equation is for depths above 2 km (6561.68 ft) and a second equation is for depths below 2 km (6561.68 ft).

14. The method according to claim 13, wherein the first equation is an exponential relationship between porosity and depth.

15. The method according to claim 13, wherein the second equation is an exponential relationship between porosity and depth.

16. The method according to claim 12, wherein the cementation model uses a kinetical-controlled quartz cementation model from Lander and Walderhaug.

17. The method according to claim 12, wherein the diagenesis model further outputs with each depositional time: compacted porosity, effective reaction surface area, volume of the quartz cement, volume of illite cement, final porosity, and final permeability.

18. The method according to claim 12, wherein the diagenesis model predicts the permeability map by Kozeny-Carman equation.

19. The method according to claim 12, wherein the diagenesis model is calibrated by adjusting the parameters of the diagenesis model.
